(19) United States
(12) Patent Application Publication
(10) Pub. No.: US 2006/0133049 A1
(43) Pub. Date: Jun. 22, 2006

(54) Electronic apparatus and display apparatus equipped with the electric apparatus

(75) Inventor: Hiroshi Hagiwara, Fukaya-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/313,751

(22) Filed: Dec. 22, 2005

(30) Foreign Application Priority Data
Dec. 22, 2004 (JP) 2004-371873

(51) Int. Cl. H05K 7/20

(52) U.S. Cl. 361/720

(57) ABSTRACT

An electric apparatus includes a semiconductor device, a printed substrate, a shield case, a thermally conductive sheet, and a heat radiation member. The semiconductor device is mounted on the printed substrate stored in the shield case. The shield case has a hole portion opened toward the semiconductor device. The thermally conductive sheet is attached to the semiconductor device disposed in a position opposed to the hole portion. The heat radiation member is attached to the hole portion, an inner end portion abuts on the thermally conductive sheet, and an outer end portion protrudes out of the shield case. Heat generated in the semiconductor device is released to the outside of the shield case via the thermally conductive sheet and the heat radiation member.

### CROSS-REFERENCE TO RELATED APPLICATIONS

This application is based upon and claims the benefit of priority from prior Japanese Patent Application No. 2004-371873, filed Dec. 22, 2004, the entire contents of which are incorporated herein by reference.

### BACKGROUND OF THE INVENTION

1. Field of the Invention

The present invention relates to an electronic apparatus which considers noise and heat generated from a semiconductor device mounted on a substrate, and a display apparatus including the electronic apparatus.

2. Description of the Related Art

A display apparatus of a liquid crystal television or the like includes a plurality of electronic apparatuses. Each of these electronic apparatuses is equipped with a plurality of printed substrates constituting a signal processing circuit and the like on which electronic parts and semiconductor devices are mounted. The semiconductor devices mounted on the printed substrates generate, when they perform high-speed data processing, not only an electromagnetic wave that becomes noise but also heat. To block the electromagnetic wave generated from the semiconductor devices in the electronic apparatus, the printed substrates are stored in a metallic shield case.

However, when the printed substrates are covered with the shield case, the heat, which is generated from the semiconductor devices on the printed substrates in each electronic apparatus, is confined in the shield case, and in consequence, a temperature in the shield case rises. When electronic parts are exposed to a high temperature, unfavorable situations may occur. For example, operation of the electronic apparatus becomes unstable, or its performance deteriorates.

To solve the problems that occur on the electronic apparatus owing to the temperature rise in the shield case, various proposals have been made as means which are arranged in the shield case to eliminate the heat of heat generating parts such as the semiconductors, and some of them are in practical use.

An IC heat radiation structure described in Jpn. UM Appln. KOKOKU Publication No. 2-17485 is constituted of a housing whose cross section is H-shaped, a substrate on which ICs are mounted, a hole which is disposed through an inside plate of the housing and into which the ICs are inserted, a shield plate which is attached to the inside plate of the housing from a side opposite to the substrate and which has a screw hole at a position corresponding to the hole, and a screw that is screwed into the screw hole while a thermal compound is interposed between the ICs.

The housing, the shield plate and the screw shield the ICs electrically and magnetically, and furthermore they are made of metals having excellent thermal conductivity. The heat generated from the ICs is exhausted from the housing through the thermal compound, the screw, the shield plat and the inside plate of the housing in succession.

However, in the IC heat radiation structure described in Jpn. UM Appln. KOKOKU Publication No. 2-17485, the shield plate is arranged in a space closed by the housing and an upper cover, and the screw is screwed into the shield plate. Therefore, the heat released from the screw and the shield plate remains in the space, which may raise a temperature of the space. When the temperature of the space rises, it is inhibited that the heat generated from the ICs is efficiently conducted through the screw to the shield plate, and in consequence, heat radiation efficiency deteriorates.

### BRIEF SUMMARY OF THE INVENTION

An electric apparatus includes a semiconductor device, a substrate, a shield case, a thermally conductive member, and a heat radiation member. The semiconductor device generates heats during arithmetic processing. The substrate is equipped with the semiconductor device. The shield case, which is made of a material that blocks an electromagnetic wave, stores the substrate, and is provided a hole portion that is opened toward the semiconductor device. The thermally conductive member is attached to the semiconductor device disposed in a position opposed to the hole portion. The heat radiation member is put in the hole portion, an inner end portion of the heat radiation member abuts on the thermally conductive member, and an outer end portion of the member protrudes out of the shield case.

The heat generated in the semiconductor device is released to the outside of the shield case mainly via the thermally conductive member and the heat radiation member.

Objects and advantages of the invention will become apparent from the description which follows, or may be learned by practice of the invention.

### BRIEF DESCRIPTION OF THE SEVERAL VIEWS OF THE DRAWING

The accompanying drawings illustrate embodiments, and together with the general description given above and the detailed description given below, serve to explain the principles of the embodiments.

FIG. 1 is a perspective view showing a display apparatus according to a first embodiment of the present invention;

FIG. 2 is an exploded perspective view of an electric apparatus built in the display apparatus shown in FIG. 1;

FIG. 3 is a perspective view showing a process in which a heat radiation member of the electric apparatus shown in FIG. 2 is attached;

FIG. 4 is a perspective view of the electric apparatus shown in FIG. 1;

FIG. 5 is a sectional view of the electric apparatus shown along line F5-F5 of FIG. 1;

FIG. 6 is a sectional view of an electric apparatus according to a second embodiment of the present invention;

FIG. 7 is a perspective view showing the heat radiation member equipped in an electric apparatus according to a third embodiment of the present invention;

FIG. 8 is a perspective view of an electric apparatus in which the heat radiation member shown in FIG. 7 is attached to the hole portion of a shield case; and

FIG. 9 is a perspective view showing an electric apparatus according to a fourth embodiment of the present invention.

### DETAILED DESCRIPTION OF THE INVENTION

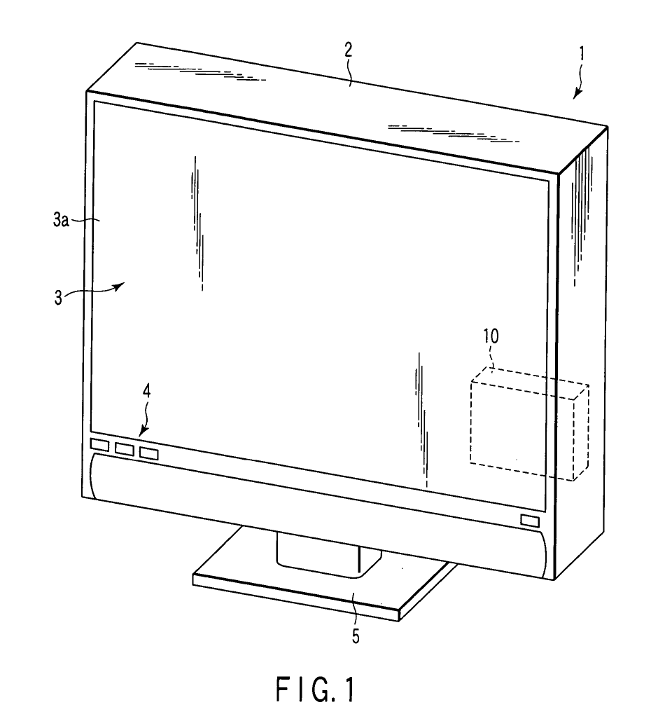

A television receiving device 1 in which an electric apparatus 10 of a first embodiment according to the present invention will be described with reference to FIGS. 1 to 5. The television receiving device 1 shown in FIG. 1 is one example of a display apparatus, and is provided with an outer housing 2, a display device 3, an operating section 4, a support stand 5, and the electric apparatus 10. The outer housing 2 has a thin box shape. The display device 3 having a flat outer shape has a display surface 3a which indicates an image. The outer housing 2 covers an outer peripheral portion of the display device 3 excluding the display surface 3a.

In the television receiving device 1, a surface of the outer housing 2 to which the display surface 3a is exposed is regarded as a front, and an opposite surface is regarded as a rear. The operating section 4 is disposed on the front of the outer housing 2 outside the display surface 3a, and has a plurality of operation buttons. The support stand 5 supports the outer housing 2. The electric apparatus 10 is built in the outer housing 2, and disposed behind of the display device 3. In the outer housing 2 of the television receiving device 1, the electric apparatus 10 may be integrated or divided into a plurality of sections.

It is to be noted that applied examples of the display device 3 include a cathode ray tube (CRT) type display device, a liquid crystal display (LCD), a plasma display device, and an electro luminescent display (EL display).

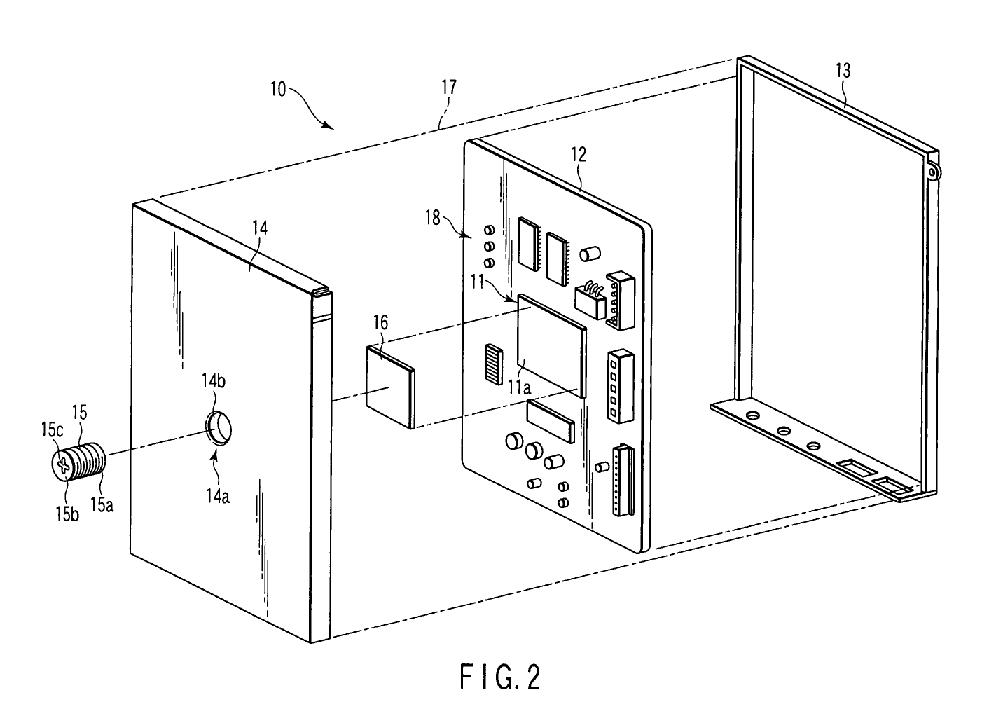

An exploded perspective view of the electric apparatus 10 shown in FIG. 2 shows a state seen from the rear side. As shown in FIG. 2, the electric apparatus 10 is provided with a shield case 17, a printed substrate 12, an image signal processing circuit 18, a semiconductor device 11, a thermally conductive sheet (thermally conductive member) 16, and a heat radiation member 15. The shield case 17 is formed of a material which blocks an electromagnetic wave and which has a metal-made box-like outer shape, and constituted of a case frame 13 and a case shell 14.

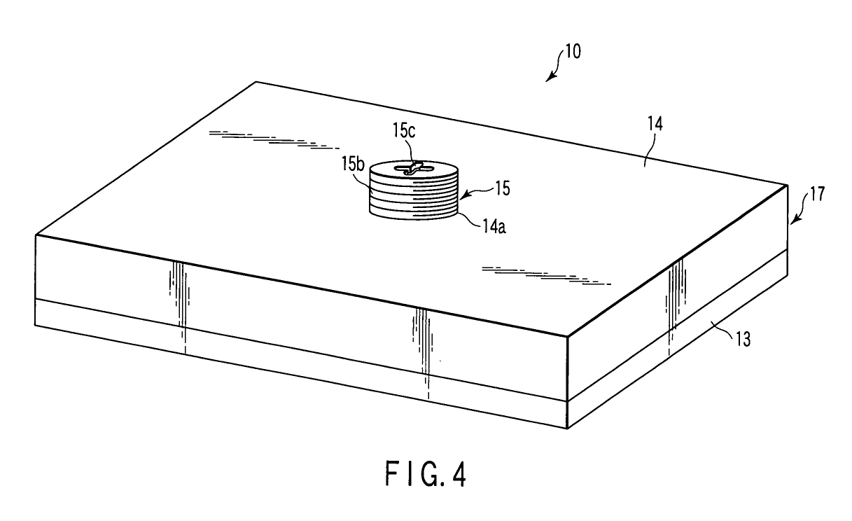

The case frame 13 is disposed in a direction along the display device 3, and the case shell 14 is disposed on the side of the rear in the television receiving device 1. The case frame 13 and the case shell 14 are formed by bending thin-plate members superior in thermal conductivity. Outer peripheral edges of the case frame 13 and the case shell 14 are integrally fitted into each other to form a box-type appearance shown in FIG. 4.

The printed substrate 12 is arranged in parallel with the display surface 3a of the display device 3, stored in the shield case 17, and attached on the case frame 13 side. An image signal processing circuit 18 including the semiconductor device 11 and a plurality of electronic components is mounted on the printed substrate 12. The printed substrate 12 is one example of a substrate, and may be provided with a tuner in addition to the image signal processing circuit 18.

The image signal processing circuit 18 executes arithmetic processing of an image signal displayed on the display surface 3a. The semiconductor device 11 is an IC which performs the arithmetic processing at a high speed, and generates an electromagnetic wave constituting a noise, and heat due to an inner resistance. The semiconductor device 11 is mounted facing the side of the case shell 14.

In the case shell 14, a hole portion 14a opens toward the semiconductor device 11. A specific position of the hole portion 14a is a position facing a so-called upper surface of the semiconductor device 11 mounted on the printed substrate 12 stored in the shield case 17.

The thermally conductive sheet 16 is one aspect of a high-heat conductive member, and attached to the surface of the semiconductor device 11 disposed in a position facing the hole portion 14a. The thermally conductive sheet 16 is a member having elasticity and flexibility, and formed of a silicone-based material, a non-silicone-based material represented by an acryl rubber, or composite materials which sandwich aluminum or carbon graphite.

The heat radiation member 15 is formed of a material superior in thermal conductivity, and is inserted into the hole portion 14a. The heat radiation member 15 has such a size as to protrude an outer end portion 15b to the outside of the shield case in a state in which an inserted inner end portion 15a is brought into contact with the thermally conductive sheet 16. The heat radiation member 15 has a columnar shape, an external thread is formed on an outer peripheral surface of the member, the inner end portion 15a is flatly formed, and the outer end portion 15b is provided with a fitting portion to be fitted into a driver. The heat radiation member 15 is constituted by forming a tip surface of a so-called set screw to be flat.

The hole portion 14a has a reduced diameter portion whose inner-diameter dimension becomes smaller than an outer diameter of the heat radiation member 15 from the outside toward the inside of the shield case in a state before the heat radiation member 15 is inserted, that is, a tapered portion 14b in the present embodiment. When the heat radiation member 15 is attached to the tapered portion 14b, an internal thread is formed.

A procedure to assemble the electric apparatus 10 will be described hereinafter.

First, there are prepared the case frame 13 and the case shell 14 constituting the shield case 17, the printed substrate 12 on whose mounting surface a plurality of electronic components are mounted including the semiconductor device 11, the thermally conductive sheet 16 having a predetermined elasticity with a predetermined thickness and size, the heat radiation member 15 and the like.

Next, the thermally conductive sheet 16 is attached to an upper surface 11a of the semiconductor device 11 mounted on the printed substrate 12. Moreover, the printed substrate 12 is fixed to the case frame 13. It is to be noted that the thermally conductive sheet 16 may be attached to the upper surface of the semiconductor device 11 mounted on the printed substrate 12 after fixing the printed substrate 12 to the case frame 13.

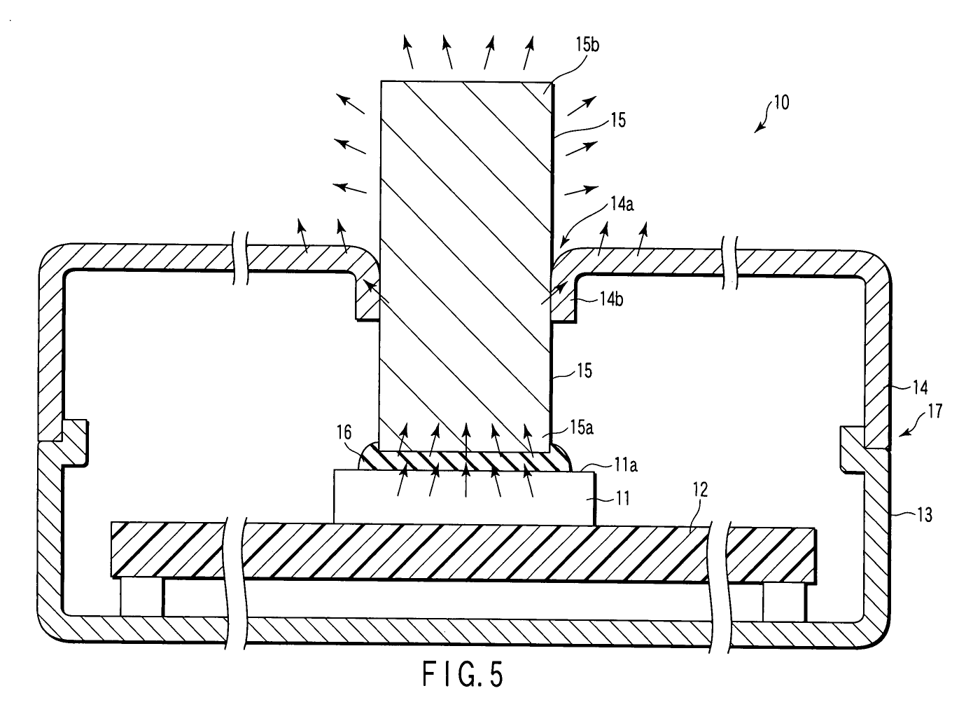

When the case shell 14 is integrally attached to the case frame 13 fixed to the printed substrate 12, the shield case 17 is constituted. In this case, the upper surface of the case shell 14 and the printed substrate 12 have a parallel positional relation as shown in FIG. 5.

Finally, the heat radiation member 15 is screwed into the hole portion 14a formed in the case shell 14. In this case, the inner end portion 15a of the heat radiation member 15 abuts on the tapered portion 14b, and the inner end portion 15a of the heat radiation member 15 is brought into such a state as to face the hole portion 14a. A central axis of the heat radiation member 15 is preferably perpendicular to the upper surface 11a of the semiconductor device 11.

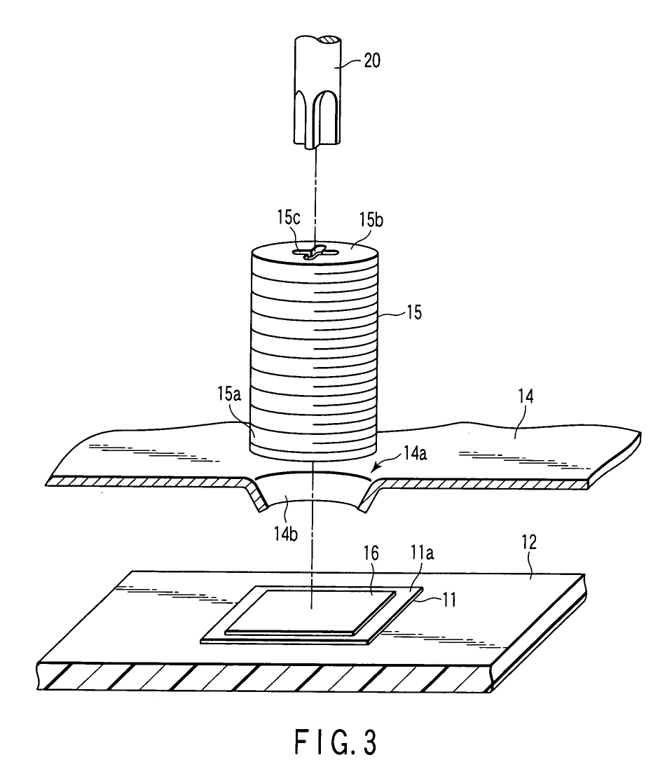

A tip portion of a driver 20 is fitted into a fitting recessed portion 15c of the heat radiation member 15, and the driver 20 is rotated in a screwing direction. It is to be noted that a tip shape of the driver 20 is not limited to a plus shape shown in FIG. 3, and may be a minus shape, a three-pointed star shape, or a five-pointed star shape in accordance with the shape of the fitting recessed portion 15c disposed in the heat radiation member 15.

When an external thread formed on the heat radiation member 15 is engaged with an inner periphery of the tapered portion 14b of the hole portion 14a, and rotated by the driver 20, the inner end portion 15a of the heat radiation member 15 gradually enters the shield case 17.

It is detected by a torque change that the inner end portion 15a of the heat radiation member 15 abuts on the thermally conductive sheet 16 attached to the upper surface 11a of the semiconductor device 11. Thereafter, a pressing force with respect to the semiconductor device 11 is considered beforehand, and the driver 20 is rotated by a preset rotation angle, for example, by one turn. Through the above-described series of flow, an operation to attach the heat radiation member 15 to the case shell 14 is completed.

In this state, the inner end portion 15a of the heat radiation member 15 abuts on the thermally conductive sheet 16 as shown in FIG. 5, and the outer end portion 15b of the heat radiation member 15 protrudes by a certain length from an outer side surface of the case shell 14 as shown in FIG. 4.

In the electric apparatus 10 constituted as described above, the semiconductor device 11 mounted on the printed substrate 12 is stored in the shield case 17. Therefore, the electromagnetic wave generated from the semiconductor device 11 is interrupted without being radiated to the outside of the shield case 17.

In the present embodiment, the inner end portion 15a of the heat radiation member 15 is flatly formed in consideration of close attachment to the thermally conductive sheet 16. As shown in FIG. 5, the inner end portion 15a of the heat radiation member 15 is pressed onto the thermally conductive sheet 16 in a state in which the portion is assembled to the case shell 14, and the inner end portion 15a sinks the thermally conductive sheet 16. The inner end portion 15a of the heat radiation member 15 and the outer peripheral surface of the heat radiation member in the vicinity of the inner end portion are closely attached to the thermally conductive sheet 16.

The electric apparatus 10 has a constitution in which the thermally conductive sheet 16 is sandwiched between the upper surface 11a of the semiconductor device 11 and the inner end portion 15a of the heat radiation member 15. The heat generated by the semiconductor device 11 is transmitted to the thermally conductive sheet 16 and further to the heat radiation member 15 as shown by arrows in FIG. 5. The heat transmitted to the heat radiation member 15 is released from the surface of the outer end portion 15b which protrudes out of the case shell 14 to the outside of the shield case 17. The heat is also transmitted to the shield case 17 via a screw portion, and released from the outer surface of the shield case 17.

Since the thermally conductive sheet 16 is formed of a material superior in thermal conductivity, and has elasticity and flexibility, the sheet has three functions. The first function is a function of a cushioning member which prevents a large pressing force from being directly applied from the heat radiation member 15 to the semiconductor device 11. The second function is a function of setting the closely attached state of the inner end portion 15a of the heat radiation member 15 to be uniform. The third function is a function of transmitting the heat generated in the semiconductor device 11 to the heat radiation member 15.

In the present embodiment, the electric apparatus 10 has the thermally conductive sheet 16 on the upper surface 11a of the semiconductor device 11 mounted on the printed substrate 12 stored in the shield case 17. The inner end portion 15a of the heat radiation member 15 attached to the case shell 14 constituting the shield case 17 is closely attached to the thermally conductive sheet 16. The outer end portion 15b of the heat radiation member 15 appropriately protrudes from the case shell 14.

When the electric apparatus 10 is constituted in this manner, the heat generated by the semiconductor device 11 is transmitted to the heat radiation member 15 via the thermally conductive sheet 16. The heat conducted to the heat radiation member 15 is released from the outer end portion 15b of the heat radiation member 15 to the outside of the shield case 17. Moreover, the heat is transmitted to the shield case 17, and released from the shield case 17.

The electric apparatus 10 prevents the heat generated from the semiconductor device 11 from being confined in the shield case 17 to thereby prevent an operation of the electric apparatus 10 from being unstable or prevent performance from being deteriorated.

Moreover, in a case where the upper surface 11a of the semiconductor device 11 is closely attached to the tip surface of the inner end portion 15a of the heat radiation member 15 via the thermally conductive sheet 16, the driver 20 is rotated by a preset amount, after confirming that the tip surface of the heat radiation member 15 abuts on the thermally conductive sheet 16. Therefore, a large load can be prevented from being applied from the heat radiation member 15 to the semiconductor device 11.

Even in a case where there is an error in a thickness dimension or elasticity of the thermally conductive sheet 16, the closely attached state of the tip surface of the inner end portion 15a of the heat radiation member 15 to the thermally conductive sheet 16 is substantially uniform.

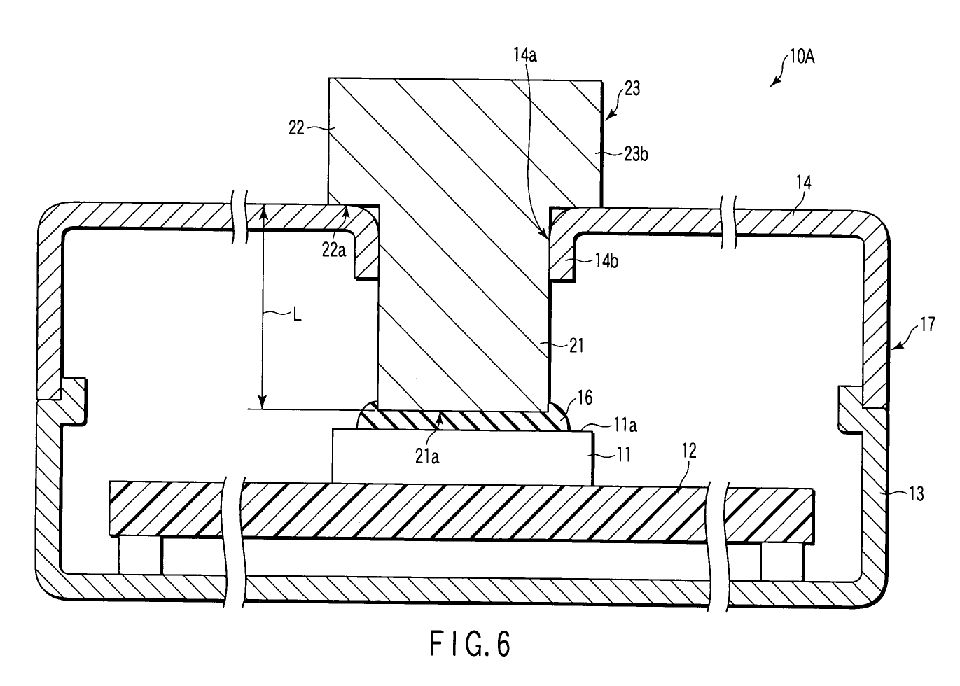

A heat radiation member 23 provided in an electric apparatus 10A according to a second embodiment of the present invention will be described with reference to FIG. 6. The components that have the same functions as the electric apparatus 10 described in the first embodiment will respectively applying the same reference symbols and may omit the description from followings. In the first embodiment, the heat radiation member 15 has a columnar rod shape whose outer peripheral surface is provided with an external thread. Comparing to the first embodiment, the heat radiation member 23 has a columnar portion 21 and an enlarged diameter portion 22 as shown in FIG. 6 in the second embodiment.

The external thread is formed on the outer peripheral surface of the columnar portion 21. The enlarged diameter portion 22 protrudes out of a case shell 14 in a state in which the heat radiation member 23 is attached to the case shell 14, and a diameter of the enlarged diameter portion is larger than that of the columnar portion 21. As shown in FIG. 6, in consideration of a thickness dimension and elasticity of a thermally conductive sheet 16, a length dimension L from an abutment surface 22a of the enlarged diameter portion 22 which abuts on an outer side surface of the case shell 14 to a tip surface 21a of the columnar portion 21 is set to such an appropriate dimension that the tip surface 21a, which is also an end surface of an inner end portion of the heat radiation member 23, is closely attached to the thermally conductive sheet 16.

In a case where the heat radiation member 23 is constituted as described above, it is recognized that the tip surface 21a of the heat radiation member 23 is closely attached to the thermally conductive sheet 16 as desired, and the attaching of the heat radiation member 23 is completed, by confirming that the abutment surface 22a of the enlarged diameter portion 22 abuts on the outer side surface of the case shell 14, when the heat radiation member 23 is screwed into a hole portion 14a by a driver 20.

The heat radiation member 23 is constituted of the columnar portion 21 having a predetermined length dimension, and the enlarged diameter portion 22 capable of obtaining a desired protruding amount. Therefore, the electric apparatus 10A is easily assembled into a state in which the tip surface 21a of the heat radiation member 23 is closely attached to the thermally conductive sheet 16, and an outer end portion 23b of the heat radiation member 23 protrudes out of the case shell 14 as much as a desired amount, when the abutment surface 22a of the enlarged diameter portion 22 is brought into contact with the outer side surface of the case shell 14.

Moreover, the enlarged diameter portion 22 is provided on the heat radiation member 23 protruding from the case shell 14. In a case where the amount of the heat radiation member protruding from the case shell 14 is set to be equal to that of the heat radiation member 15 in the first embodiment, a surface area of the heat radiation member 23 brought into contact with atmospheric air outside the shield case 17 is, needless to say, larger. Therefore, a heat radiation efficiency is enhanced. In other words, when the surface area of the portion of the heat radiation member 23 protruding from the case shell 14 to come into contact with the atmospheric air outside the shield case 17 is set to be substantially equal to that of the heat radiation member 15 in the first embodiment, in the second embodiment, it is possible to reduce the enlarged diameter portion 22 of the heat radiation member 23 protruding from the case shell 14 and reduce an outer shape dimension of the whole electric apparatus 10A.

As described above, in the electric apparatus 10A, the heat generated from the semiconductor device 11 is not confined in the shield case 17. Hence, an operation of the electric apparatus 10A can be prevented from being unstable, and a performance thereof can be prevented from being deteriorated. Since the thermally conductive sheet 16 is interposed, the tip surface 21a of the heat radiation member 23 can be easily and securely assembled with respect to the semiconductor device 11 with an appropriate pressing force. As a result, a heat transmitting path from the semiconductor device 11 to the heat radiation member 23 is securely assured.

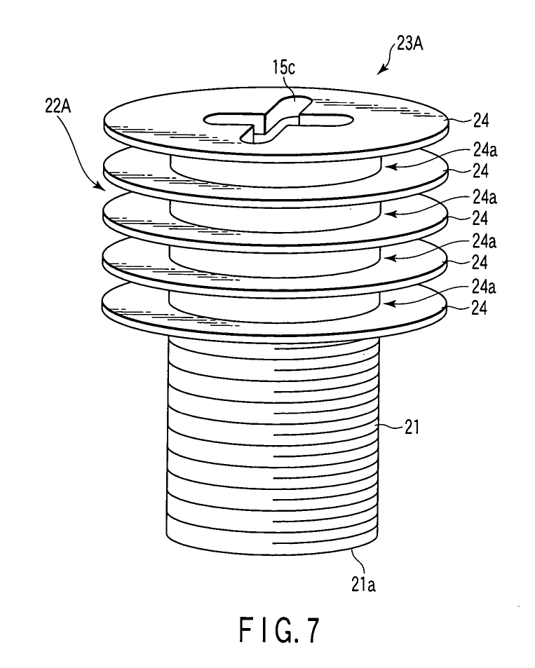

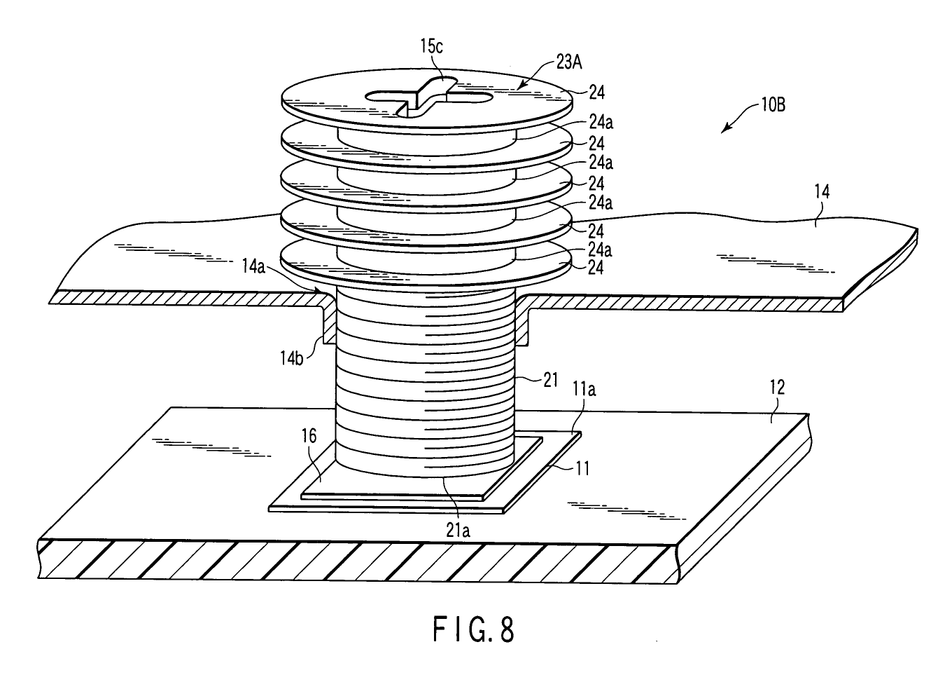

A heat radiation member 23A disposed on an electric apparatus 10B according to a third embodiment of the present invention will be described with reference to FIGS. 7 and 8. The components that have same functions as that of the heat radiation member 15 in the first embodiment or the heat radiation member 23 in the second embodiment will respectively applying the same reference symbols and may omit the description from followings.

As shown in FIG. 8, an inner end portion of the heat radiation member 23A of the present embodiment is closely attached to a thermally conductive sheet 16 in a state in which the heat radiation member is attached to the hole portion 14a of the case shell 14 in the same manner as in the heat radiation member 15 of the first embodiment. The heat radiation member 23A has a columnar portion 21 and an enlarged diameter portion 22A in the same manner as in the heat radiation member 23 of the second embodiment.

As shown in FIGS. 7 and 8, the enlarged diameter portion 22A is constituted of a plurality of heat radiation fins 24 spreading in a radial direction with respect to a central axis of the columnar portion 21, and gaps 24a each disposed between the heat radiation fins 24. The heat radiation fin 24 arranged closest to the columnar portion 21 is set in such a manner that a tip surface 21a of the inner end portion of the heat radiation member 23A inserted in the case shell 14 of a shield case 17 is closely attached to the thermally conductive sheet 16.

Especially, a length of the columnar portion 21 is set to a dimension L to such an extend that the thermally conductive sheet 16 is compressed by the tip surface 21a of the columnar portion 21 while the heat radiation fin 24 arranged closest to the columnar portion 21 abuts on the case shell 14. Accordingly, an assembling operation is facilitated, and a sectional area of a heat transmitting path from the semiconductor device 11 to the heat radiation member 23A is enlarged in the same manner as in the heat radiation member 23 of the second embodiment.

Since the enlarged diameter portion 22A has a plurality of heat radiation fins 24 in the heat radiation member 23A constituted as described above, a surface area of a portion of the heat radiation member exposed to the outside of the shield case 17 is large as compared with the heat radiation member 15 of the first embodiment or the heat radiation member 23 of the second embodiment. That is, since the electric apparatus 10B is provided with the heat radiation member 23A, the apparatus has a high capability to release the heat generated in the semiconductor device 11 to the outside of the shield case 17.

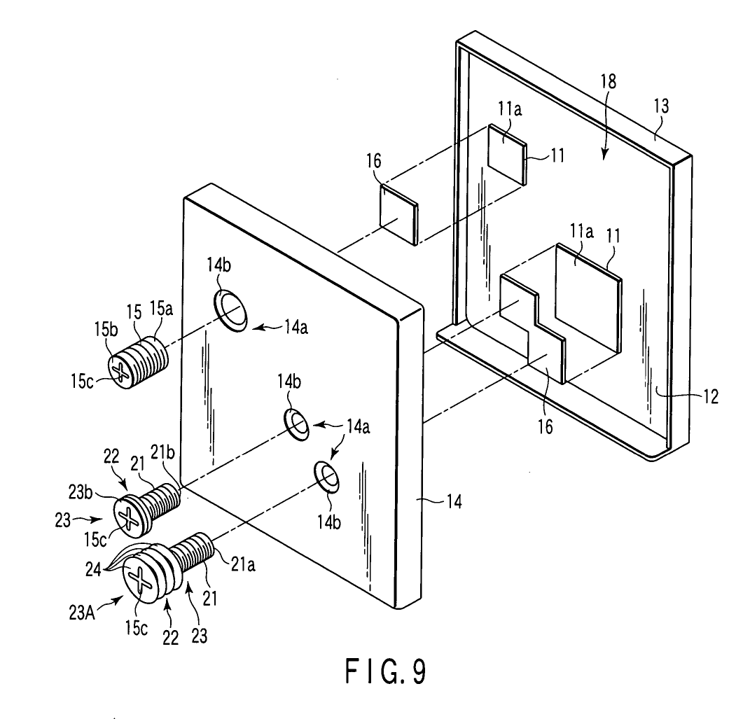

An electric apparatus 10C according to a fourth embodiment of the present invention will be described with reference to FIG. 9. A components that have the same function as that of each of the electric apparatus 10 of the first embodiment, the electric apparatus 10A of the second embodiment, and the electric apparatus 10B of the third embodiment is denoted with the same reference symbols and may omit the description from followings. The electric apparatus 10C is built in, for example, a display apparatus in the same manner as in the electric apparatus 10 of the first embodiment.

In the electric apparatus 10C shown in FIG. 9, a semiconductor device 11 is one of electronic components constituting an information processing circuit, and releases an electromagnetic wave and heat during arithmetic processing. A plurality of semiconductor devices, two semiconductor devices in the present embodiment are mounted on a printed substrate 12. A case shell 14 has hole portions 14a in positions corresponding to the semiconductor devices 11 mounted on the printed substrate 12 fixed to a case frame 13.

Especially in the present embodiment, two hole portions 14a are prepared with respect to the semiconductor device 11 having a larger area on the printed substrate 12. The hole portion 14a corresponding to the semiconductor device 11 having a smaller area has a diameter larger than that of the hole portion 14a prepared with respect to the semiconductor device 11 having the larger area. Heat radiation members 15 are attached to the respective hole portions 14a in accordance with the diameters of the hole portions.

In the electric apparatus 10C shown in FIG. 9, heat radiation members 23, 23A having different heat radiating areas of portions protruding out of a shield case 17 are attached to the semiconductor device 11 having the large area. In a case where an amount of heat generated per unit time during the arithmetic processing differs with a section of the semiconductor device 11, the heat radiation member may be appropriately arranged in such a manner as to match an amount of heat released per unit time with the amount of the heat generated in a certain area.

Moreover, as to a shape of each thermally conductive sheet 16 to be attached to each semiconductor device 11, as shown in FIG. 9, the sheets may be arranged in positions corresponding to the heat radiation members 15, 23, and 23A. Therefore, the sheet may have a square shape or a composite shape matched with an outer shape of the semiconductor device 11. Additionally, the sheet may have a circular shape in accordance with the outer shapes of the heat radiation members 15, 23, and 23A.

In the above-described first to fourth embodiments, the hole portion 14a has a tapered portion 14b which is a reduced diameter portion narrowed down to an opening area smaller than the outer shape of each of the heat radiation members 15, 23, and 23A before the heat radiation members 15, 23, and 23A are inserted. Therefore, even when the case shell 14 is expanded owing to the heat generating of the semiconductor device 11, and the opening area of the hole portion 14a is slightly enlarged, a gap is not easily generated between the hole portion 14a and each of the heat radiation members 15, 23, and 23A. Since the thermally conductive sheet 16 has elasticity, the heat radiation members 15, 23, and 23A are not detached from the thermally conductive sheet 16 even in a case where the case shell 14 is displaced in a direction left away from the semiconductor device 11.

It is to be noted that in each of the embodiments, the external thread is formed on the outer peripheral surface of the heat radiation member 15, but an annular groove may be formed instead of the external thread. In this case, the groove is formed in such a position that the tip surface of the inner end portion of the heat radiation member 15 is appropriately closely attached to the thermally conductive sheet 16 attached to the semiconductor device 11.

Moreover, each of the heat radiation members 15, 23, and 23A has a columnar shape, but may have a square rod shape. In this case, since the heat radiation member having the square rod shape cannot be screwed in with a driver, a groove to be engaged with the end portion of a contractive portion is formed along an outer periphery of the square rod so that the inner end portion of the heat radiation member is appropriately closely attached to the thermally conductive member.

As described above, in the electric apparatuses 10, 10A, 10B, and 10C, the heat generated from the semiconductor device 11 mounted on the printed substrate 12 stored in the shield case 17 that interrupts the electromagnetic wave is released to the outside of the shield case 17. Therefore, in the electric apparatuses 10, 10A, 10B, and 10C, it is possible to prevent the operations of each electric apparatus itself and the display apparatus containing this electric apparatus from being unstable owing to the heat, and it is also possible to prevent the performance from being deteriorated.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the inventive as defined by the appended claims and equivalents thereof.

What is claimed is:

1. An electric apparatus comprising:
a semiconductor device which generates heat during arithmetic processing;
a substrate on which the semiconductor device is mounted;
a shield case which is made of a material to block an electromagnetic wave, said shield case stores the substrate and has a hole portion opened toward the semiconductor device;
a thermally conductive member attached to the semiconductor device in a position opposed to the hole portion; and
a heat radiation member which is attached to the hole portion while an inner end portion of the heat radiation member abuts on the thermally conductive member and whose outer end portion protrudes out of the shield case.

2. The electric apparatus according to claim 1, wherein said shield case is constituted of:
a case frame which supports the substrate from a side opposite to a side on which the semiconductor device is mounted; and
a case shell in which the hole portion is disposed and which covers the substrate and which is disposed integrally with the case frame.

3. The electric apparatus according to claim 1, wherein
said heat radiation member has a columnar shape whose outer peripheral surface is provided with an external thread.

4. The electric apparatus according to claim 1, wherein
said hole portion has a reduced diameter portion whose opening sectional area is reduced from the outside toward the inside of the shield case until the opening sectional area becomes smaller than an insertion sectional area of the heat radiation member in a state before the heat radiation member is inserted.

5. The electric apparatus according to claim 1, wherein
said outer end portion of the heat radiation member has an enlarged diameter portion provided with an abutment surface which comes into contact with an outer surface of the case shell while the inner end portion is brought into contact with the thermally conductive member.

6. The electric apparatus according to claim 1, wherein
said outer end portion of the heat radiation member has a fin which extends in a direction along an outer surface of the shield case.

7. The electric apparatus according to claim 1, wherein
said thermally conductive member is a thermally conductive sheet having elasticity which can be compressed, and
said inner end portion of the heat radiation member is flatly formed to be closely attached to the thermally conductive sheet.

8. A display apparatus comprising:
a display device which has a flat outer shape and which indicates an image in a display surface;
an outer housing which covers an outer peripheral portion of the display device excluding the display surface;
an image signal processing circuit which executes an operation relating to an image signal displayed on the display surface;
a semiconductor device included in the image signal processing circuit;
a substrate on which the semiconductor device is mounted and which is arranged between the display device and the outer housing along the display surface;
a shield case which is made of a material to block an electromagnetic wave, said shield case stores the substrate and has a hole portion opened toward the semiconductor device;
a thermally conductive member attached to the semiconductor device in a position opposed to the hole portion; and
a heat radiation member which is put in the hole portion while an inner end portion of the heat radiation member abuts on the thermally conductive member and whose outer end portion protrudes out of the shield case.

9. The display apparatus according to claim 8, wherein
said heat radiation member has a columnar shape whose outer peripheral surface is provided with an external thread.

10. The display apparatus according to claim 8, wherein
said hole portion has a reduced diameter portion whose opening sectional area is reduced from the outside toward the inside of the shield case until the opening sectional area becomes smaller than an insertion sectional area of the heat radiation member in a state before the heat radiation member is inserted.
